(19) United States
(12) Patent Application Publication
(10) Pub. No.: US 2012/0327615 A1
(43) Pub. Date: Dec. 27, 2012

(54) PROTECTIVE CASING

(76) Inventors: Eric Waters, Santa Clara, CA (US); Stig Pedersen, Santa Clara, CA (US); Shu Chi Peggy Fong, Santa Clara, CA (US)

(21) Appl. No.: 13/170,130

(22) Filed: Jun. 27, 2011

(51) Int. Cl. H05K 5/00

(52) U.S. Cl. 361/752

(57) ABSTRACT

A protective casing equipped with positioning unit and power supply unit can be used to accommodate an electronic device, which has or hasn't a GPS positioning system. A switch disposed in the protective casing can select from different operation modes so as to activate related functions to provide positioning data and/or electrical power for the electronic device, or the protective casing simply provides water-proof and rugged protection when both the positioning unit and the power supply unit are deactivated by the switch.

### BACKGROUND OF THE INVENTION

1. Field of the Invention

The present invention relates to a protective casing, and more particularly, to a protective casing for accommodating an electronic device.

2. Description of the Prior Art

As technology advances, various electronic devices including mobile phone, media player (e.g. MP3 player), personal digital assistant (PDA) and so on, have been developed to make life more convenient and colorful. In order to protect an electronic device from harm, a user may use a protective casing to accommodate the electronic device. Conventional water-tight protective casing are seen on the market, some are embedded with battery to extend the using time of electronic device received therein. For those electronic devices with built-in positioning system, although the machine is well protected within the protective casing, the positioning accuracy and positioning speed of the electronic devices will be affected when the electronic devices are completely enclosed in the protective casing and their GPS reception is affected.

### SUMMARY OF THE INVENTION

An objective of the invention is to provide a protective casing equipped with positioning unit and auxiliary battery pack, and switch of these functions, so as to solve the aforesaid problem.

According to one embodiment of the invention, a protective casing adapted for an electronic device is provided. The protective casing includes a first casing, a second casing, and a circuit board. The second casing cooperates with the first casing to form an accommodating space therebetween. The accommodating space accommodates the electronic device. The circuit board is disposed in the accommodating space. The circuit board includes a power supply unit, a positioning unit, and a switch. The switch is electrically connecting to the power supply unit and the positioning unit for selectively activating or deactivating the power supply unit and the positioning unit. When the electronic device is accommodated in the accommodated space, a connector of the electronic device is electrically connected to a connector of the circuit board, such that the power supply unit selectively supplies power for the electronic device and the positioning unit selectively provides positioning data for the electronic device.

As mentioned in the above, since the protective casing of the invention can be used to accommodate an electronic device and provide power and positioning data for the accommodated electronic device, and the switch can selectively activate or deactivate the power unit or the positioning unit for various applicable operation modes, the protective casing of the invention can effectively enhance the functionality and the using time of the electronic device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration showing a perspective view of a protective casing in a closed state according to one embodiment of the invention.

FIG. 2 is an illustration showing the protective casing in FIG. 1 from another view angle.

FIG. 3 is an illustration showing the protective casing in FIG. 1 in an opened state.

FIG. 4 is an illustration showing the protective casing in FIG. 3 with detached back cover.

FIG. 5 is an illustration showing an exploded view of a first casing, a partition member, and a circuit board in FIG. 4.

FIG. 6(A) and FIG. 6(B) are illustrations showing the back cover in FIG. 4 used to house an electronic device from different view angles.

FIG. 7(A) and FIG. 7(B) are illustrations showing exploded views of the back cover and the electronic device in FIG. 6(A) and FIG. 6(B) from different view angles.

FIG. 8 is an illustration showing the back cover in FIG. 7 from another view angle.

FIG. 9 is an illustration showing the electronic device housed on the back cover and accommodated in the first accommodating space together with the back cover in FIG. 4.

FIG. 10 is an illustration showing the electronic device accommodated in the first accommodating space without the back cover.

### DETAILED DESCRIPTION

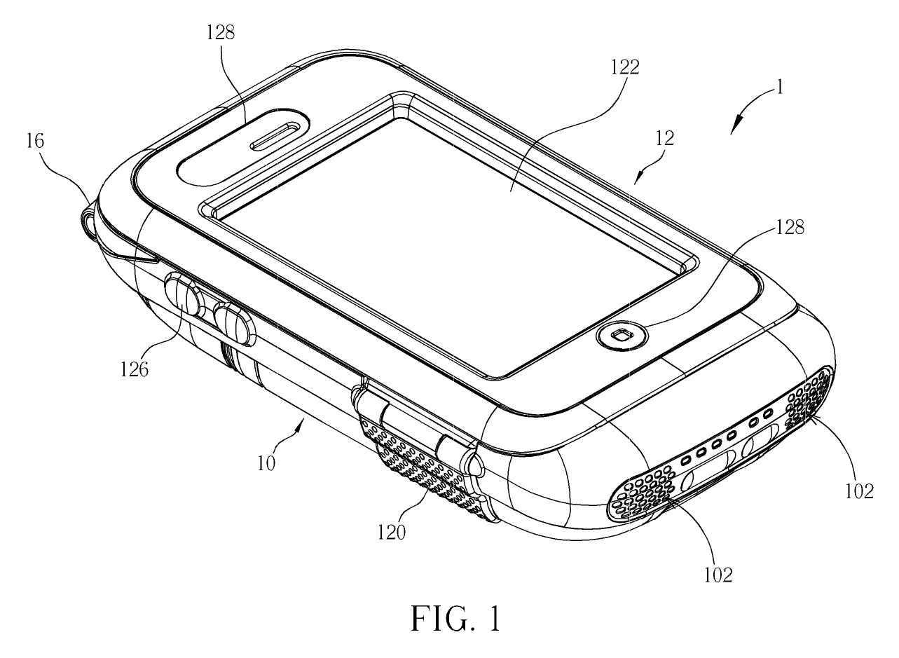

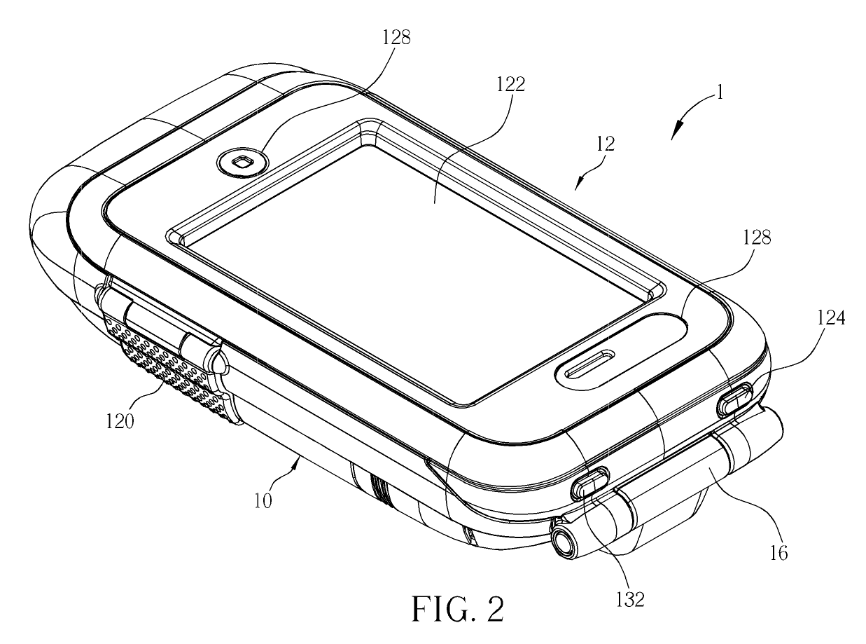

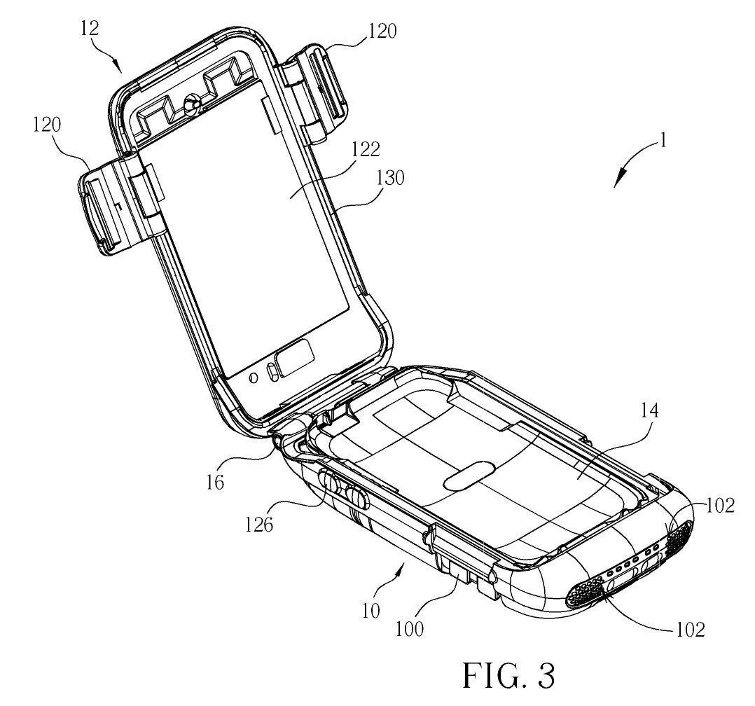

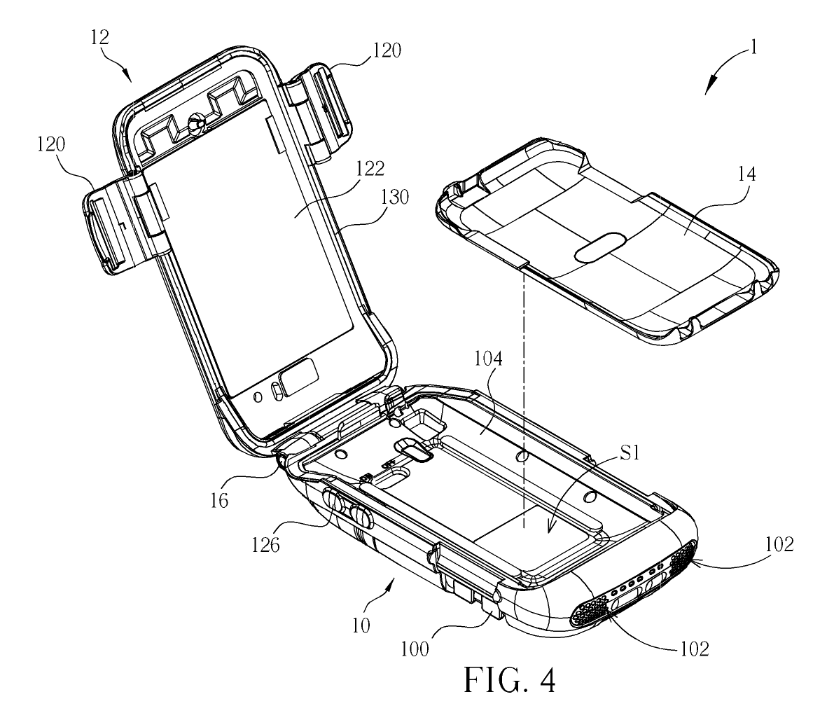

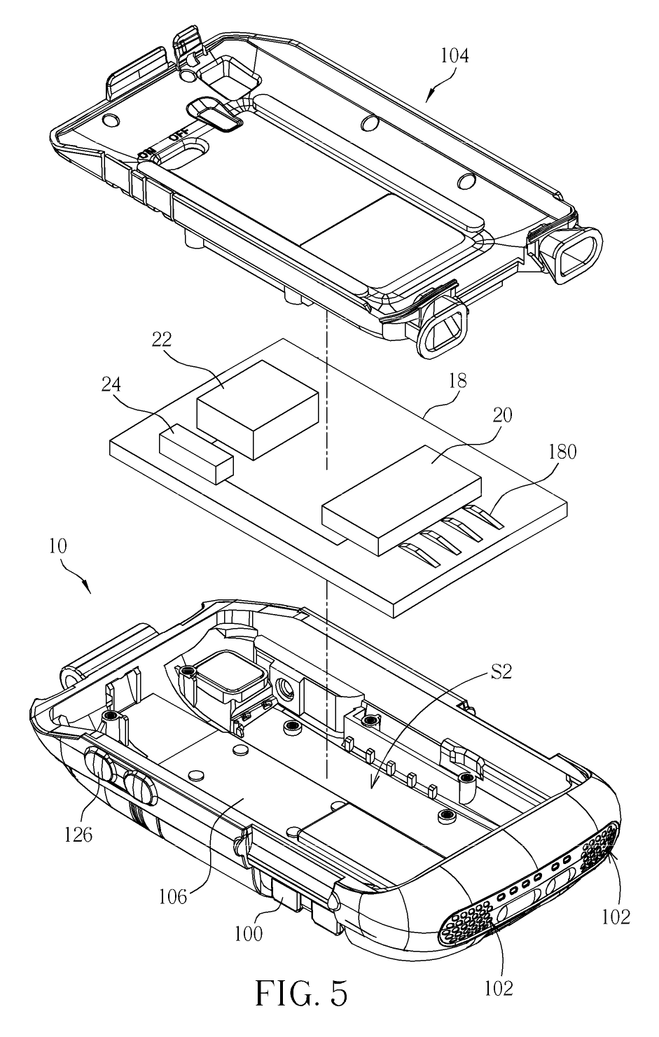

Referring to FIG. 1 to FIG. 5, FIG. 1 is an illustration showing a perspective view of a protective casing 1 in a closed state according to one embodiment of the invention, FIG. 2 is an illustration showing the protective casing 1 in FIG. 1 from another view angle, FIG. 3 is an illustration showing the protective casing 1 in FIG. 1 in an opened state, FIG. 4 is an illustration showing the protective casing 1 in FIG. 4 with detached back cover 14, and FIG. 5 is an illustration showing an exploded view of a first casing 10, a partition member 104, and a circuit board 18 in FIG. 4, the circuit board 18 hidden under a partition member 104 and not shown in FIG. 4.

As shown in FIG. 1 to FIG. 5, the protective casing 1 includes a first casing 10, a second casing 12, a back cover 14, and a circuit board 18. The first casing 10 further includes a partition member 104. The second casing 12 cooperates with the first casing 10 to form an accommodating space, which is further divided into a first accommodating space S1 and a second accommodating space S2 by the partition member 104 therebetween where the first accommodating space S1 locates above the partition member 104 and the second accommodating space S2 locates between the partition member 104 and a bottom 106 of the first casing 10. The back cover 14 can be detachably accommodated in the first accommodating space S1, as shown in FIG. 3 and FIG. 4. In this embodiment, the protective casing 1 may further include a hinge assembly 16 for pivotally connecting the second casing 12 to the first casing 10. Furthermore, the second casing 12 may include two fastener members 120 pivotally connected to opposite sides of the second casing 12, the first casing 10 may include two fastener structures 100 formed on opposite sides of the first casing 10, and the two fastener members 120 can be detachably fastened on the two fastener structures 100 respectively.

It should be noted that there is only one fastener structure 100 shown in FIG. 3 due to the view angle. As the closed state shown in FIG. 1 and FIG. 2, the two fastener members 120 are fastened on the two fastener structures 100 respectively to fix the second casing 12 and the first casing 10. On the other hand, after the two fastener members 120 are detached from the two fastener structures 100 respectively and the second casing 12 rotates with respect to the first casing 10 via the hinge assembly 16, the protective casing 1 is in the opened state as shown in FIG. 3 and FIG. 4. Accordingly, a user can operate the protective casing 1 between the closed state and the opened state.

Please refer to FIG. 5. In this embodiment of the invention, the circuit board 18 is disposed in the second accommodating space S2 and includes a power supply unit 20, a positioning unit 22, and a switch 24. The switch 24 electrically connects to the power supply unit 20 and the positioning unit 22. Practically, the power supply unit 20 may preferably be, but not limited to, a rechargeable battery with at least 1840 mAH capacity and the positioning unit 22 may be, but not limited to, a Global Positioning System (GPS).

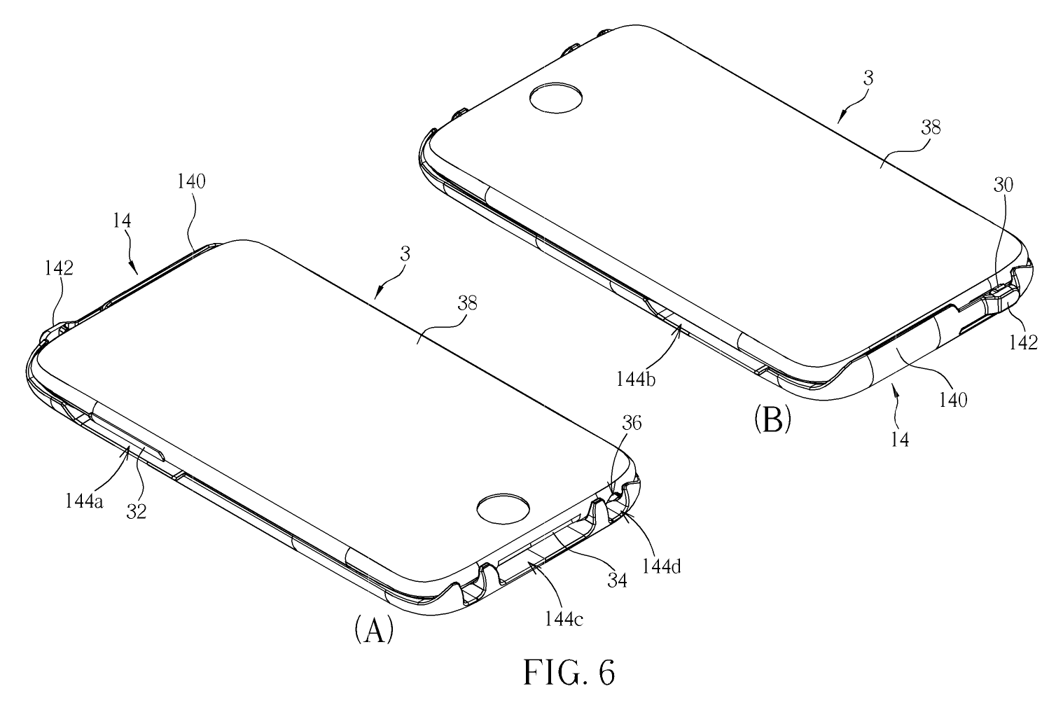

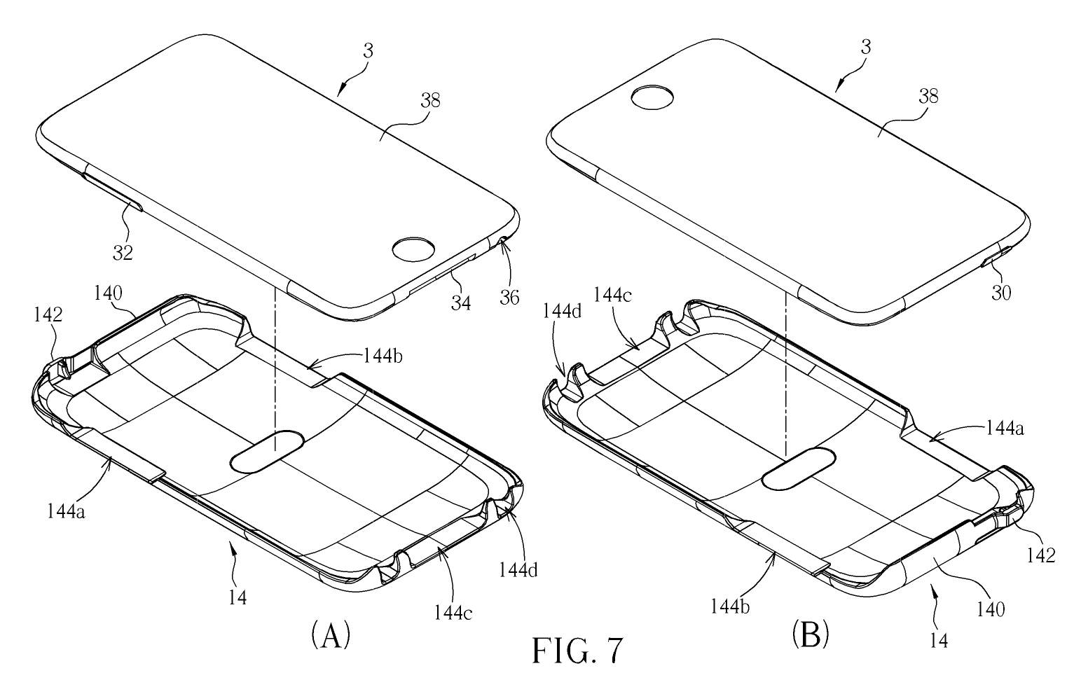

Referring to FIG. 6 and FIG. 7, FIG. 6(A) and FIG. 6(B) are illustrations showing the back cover 14 in FIG. 4 used to house an electronic device 3 from different view angles, and FIG. 7(A) and FIG. 7(B) are illustrations showing exploded views of the back cover 14 and the electronic device 3 in FIG. 6(A) and FIG. 6(B) from different view angles.

In the invention, the protective casing 1 may be applied to accommodate the electronic device 3 such as a mobile phone, a media player (e.g. MP3 player), a personal digital assistant (PDA) and so on. The electronic device 3 may be either equipped with a GPS function or not. In this embodiment, the back cover 14 has an engaging structure 140 extending from a periphery of the back cover 14, and the engaging structure 140 is used to engage the electronic device 3, such that the user can use the back cover 14 to house the electronic device 3. The engaging structure 140 may be, but not limited to, arc-shaped claws. As shown in FIG. 7, the electronic device 3 may have a power button 30, and the back cover 14 may have a resilient arm 142 extending from the periphery of the back cover 14 and corresponding to the power button 30 of the electronic device 3. As shown in FIG. 6, when the electronic device 3 is housed on the back cover 14 and engaged with the engaging structure 140, the resilient arm 142 abuts against the power button 30. Therefore, the user can press the resilient arm 142 to trigger the power button 30, so as to power on/off the electronic device 3.

In this embodiment, there may be at least one recess formed on the periphery of the back cover 14 and corresponding to at least one connector and/or button disposed on a periphery of the electronic device 3. As shown in FIG. 7, the electronic device 3 may have a button 32 (e.g. volume adjusting button) disposed on one side of the electronic device 3, so a first recess 144a may be formed on one side of the back cover 14 and corresponding to the button 32. As shown in FIG. 6, when the electronic device 3 is housed on the back cover 14 and engaged with the engaging structure 140, the button 32 is exposed from the first recess 144a. Accordingly, the user can operate the button 32 via the first recess 144a. Furthermore, a second recess 144b may be formed on another side of the back cover 14 and opposite to the first recess 144a. Accordingly, the user can grab opposite sides of the electronic device 3 via the first and second recesses 144a, 144b and then detaches the electronic device 3 from the back cover 14 easily.

Moreover, as shown in FIG. 7, there also may be other recesses 144c, 144d formed on another side of the back cover 14 and corresponding to connectors 34, 36 (e.g. USB connector, audio jack connector, etc.) disposed on the periphery of the electronic device 3. As shown in FIG. 6, when the electronic device 3 is housed on the back cover 14 and engaged with the engaging structure 140, the connectors 34, 36 are exposed from the recesses 144c, 144d respectively. Accordingly, the user can operate the connectors 34, 36 via the recesses 144c, 144d.

Please refer to FIG. 5. When the aforesaid electronic device 3 is housed on the back cover 14 and accommodated in the first accommodating space S1 together with the back cover 14, a connector (not shown) of the electronic device 3 is electrically connected to a connector 180 of the circuit board 18, such that the power supply unit 20 can selectively supply power for the electronic device 3. In this manner, the using time of the electronic device 3 can be effectively extended. The positioning unit 22 can be used to selectively provide positioning data, including received longitude/latitude data, to the electronic device 3 via the connector 180 so that the reception of GPS signals can be boosted for electronic device 3 with built-in positioning function or added for electronic device 3 without positioning function. To put it further, the positioning unit 22 can be powered by the power supply unit 20 of the protective casing 1.

To provide much more flexible application, the switch 24, either capable of moving to different positions on the circuit board 18 or being a button that can be activated or being a circuit that is controlled by the electronic device 3 when the electronic device 3 is electrically connected to the connector 180 of the circuit board 18, is used to selectively activate or deactivate the power supply unit 20 or the positioning unit 22 and set the protective casing 1 to various operation modes. The switch 24 can be exemplified as a physical sliding switch in one example. User can slide or use other operations to move the switch 24 to a designated position to set the protective casing 1 to a corresponding operation mode. In another example, the switch 24 can be exemplified as a push button. User can switch the protective casing 1 among different operation modes by pressing, clicking or activating the push button corresponding times. Yet another example, the switch 24 is a circuit controlled by the electronic device 3. The circuit receives control command from the electronic device 3 to switch the operation mode of the protective casing 1 accordingly.

The switch 24 may enable the protective casing 1 to be switched among at least three operation modes (accomplished by moving to corresponding positions or being activated corresponding times or controlled by the electronic device 3):

Mode 1 (Battery+GPS Mode): The positioning unit 22 is activated to send positioning data to the electronic device 3 and the power supply unit 20 is activated to provide power to the electronic device 3.

Mode 2 (Battery Only Mode): The power supply unit 20 is activated to provide power to the electronic device 3 and the positioning unit 22 is deactivated.

Mode 3 (Off Mode): Both the power supply unit 20 and the positioning unit 22 are deactivated and the protective casing 1 functions as a water-proof rugged case.

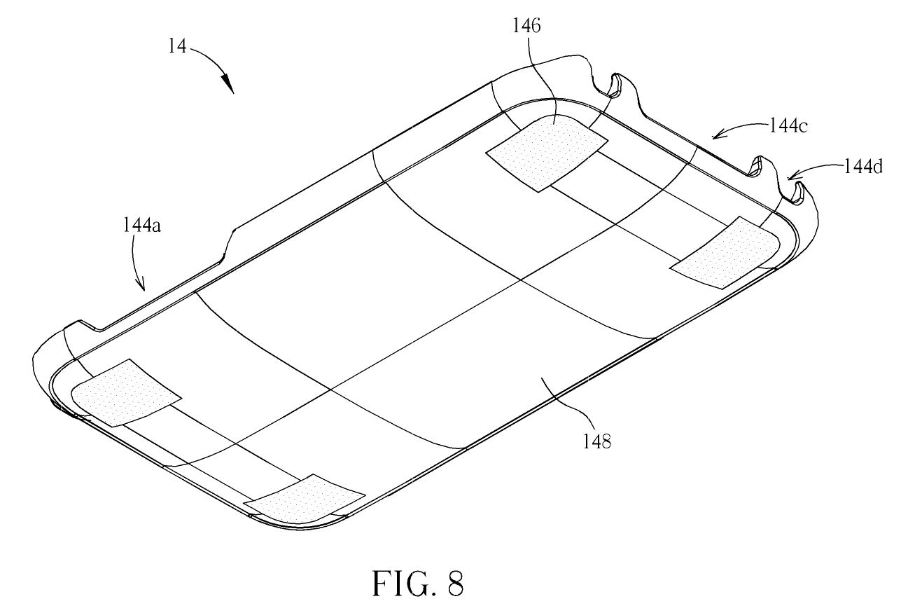

Referring to FIG. 8, FIG. 8 is an illustration showing a perspective view of the back cover 14 in FIG. 7 from another view angle. As shown in FIG. 8, a skidproof structure 146 may be formed on an outer surface 148 of the back cover 14 by surface treatment, such as texture process, printing process, laser marking process and so on. In addition, the skidproof structure 146 may be formed as various patterns for purpose of decoration.

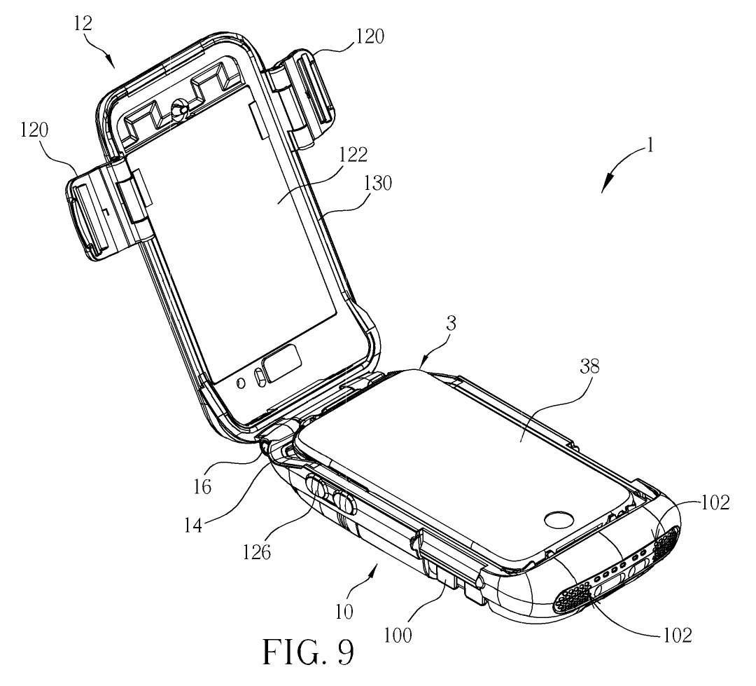

Referring to FIG. 9, FIG. 9 is an illustration showing a perspective view of the electronic device 3 housed on the back cover 14 and accommodated in the first accommodating space S1 together with the back cover 14 in FIG. 4. As shown in FIGS. 4, 6 and 9, after housing the electronic device 3 on the back cover 14, the electronic device 3 can be accommodated in the first accommodating space S1 together with the back cover 14. In this embodiment, the second casing 12 may include a transparent sheet 122 (e.g. PET film). When the electronic device 3 is accommodated in the first accommodating space S1 together with the back cover 14 and when the protective casing 1 is in the closed state (as shown in FIG. 1), a touch panel 38 of the electronic device 3 abuts against the transparent sheet 122. Accordingly, the user may perform tactile operation to the touch panel 38 via the transparent sheet 122.

Furthermore, the second casing 12 may have a key structure 124 (as shown in FIG. 2) corresponding to the resilient arm 142 of the back cover 14 (as shown in FIG. 6). In this manner, when the electronic device 3 is accommodated in the protective casing 1 together with the back cover 14, the user can press the key structure 124 to drive the resilient arm 142 to trigger the power button 30, so as to power on/off the electronic device 3. Still further, the first casing 10 may have a key structure 126 (as shown in FIG. 1) corresponding to the first recess 144a of the back cover 14 and the button 32 of the electronic device 3 (as shown in FIG. 6). In this manner, when the electronic device 3 is accommodated in the protective casing 1 together with the back cover 14, the user can press the key structure 126 to trigger the button 32 via the first recess 144a, so as to operate the button 32.

As shown in FIG. 1, there is at least one hole 128 formed on the second casing 12 for specific purposes (e.g. light emitting hole, button hole, etc.), and the second casing 12 may include at least one waterproof member (e.g. waterproof film or waterproof glue, not shown) covering the at least one hole 128 respectively, so as to prevent water from entering the protective casing 1 via the at least one hole 128. Furthermore, there is at least one hole 102 formed on the first casing 10 for specific purposes (e.g. speaker hole, microphone hole, etc.), and the first casing 10 may also include at least one waterproof member (e.g. waterproof film or waterproof glue, not shown) covering the at least one hole 102 respectively, so as to prevent water from entering the protective casing 1 via the at least one hole 102. Moreover, the second casing 12 may include a ring-shaped waterproof member 130 disposed on an inner side of the second casing 12, as shown in FIG. 3. When the protective casing 1 is in the closed state shown in FIG. 1, the ring-shaped waterproof member 130 can prevent water from entering the protective casing 1 via the junction between the second casing 12 and the first casing 10. Therefore, the protective casing 1 may serve as a water-proof case as mentioned above.

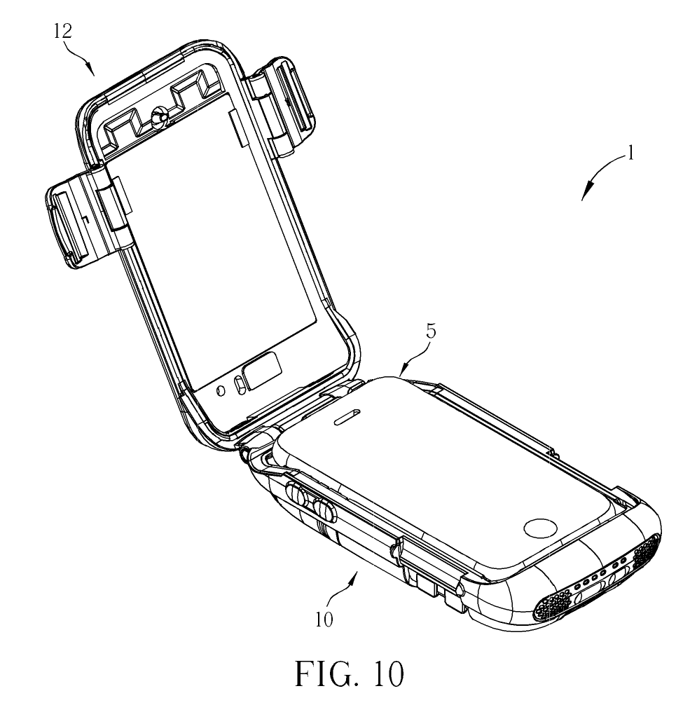

Referring to FIG. 10, FIG. 10 is an illustration of an electronic device 5 accommodated in the first accommodating space S1 without the back cover 14. As shown in FIG. 10, the size of the electronic device 5 is substantially equal to the total size of the electronic device 3 with the back cover 14. Therefore, the electronic device 5 can be accommodated in the first accommodating space S1 of the protective casing 1 immediately without the back cover 14, as shown in FIG. 10.

The protective casing of the invention equipped with positioning unit and power supply unit can be used to accommodate an electronic device, which has or hasn't a GPS positioning system. The switch disposed in the protective casing can select from different operation modes so as to activate related functions to provide positioning data and/or electrical power for the electronic device, or the protective casing simply provides water-proof and rugged protection when both the positioning unit and the power supply unit are deactivated by the switch.

Those skilled in the art will readily observe that numerous modifications and alterations of the device and method may be made while retaining the teachings of the invention.

What is claimed is:

1. A protective casing adapted for an electronic device, comprising:
a first casing;
a second casing cooperating with the first casing to form an accommodating space therebetween, the accommodating space accommodating the electronic device; and
a circuit board disposed in the accommodating space, the circuit board comprising a power supply unit, a positioning unit, and a switch, the switch electrically connecting to the power supply unit and the positioning unit for selectively activating or deactivating the power supply unit and the positioning unit;
wherein when the electronic device is accommodated in the accommodated space, a connector of the electronic device is electrically connected to a connector of the circuit board, such that the power supply unit selectively supplies power for the electronic device and the positioning unit selectively provides positioning data for the electronic device.

2. The protective casing of claim 1, further comprising a hinge assembly for pivotally connecting the first casing to the second casing.

3. The protective casing of claim 1, wherein the second casing comprises a transparent sheet which a touch panel of the electronic device abuts against when the electronic device is accommodated in the accommodating space.

4. The protective casing of claim 1, wherein the second casing comprises a key structure corresponding to a power button of the electronic device.

5. The protective casing of claim 1, wherein the second casing comprises two fastener members pivotally connected to opposite sides of the second casing, the first casing comprises two fastener structures formed on opposite sides of the first casing, and the two fastener members are detachably fastened on the two fastener structures respectively.

6. The protective casing of claim 1, wherein the second casing comprises a ring-shaped waterproof member disposed on an inner side of the second casing.

7. The protective casing of claim 1, wherein the switch enables the protective casing to be switched among a plurality of operation modes comprising: activating the power supply unit only, activating both the power supply unit and the positioning unit, and deactivating both the power supply unit and the positioning unit.

8. The protective casing of claim 7, wherein the switch switches among the operation modes by moving to different corresponding positions at the circuit board.

9. The protective casing of claim 7, wherein the switch is a button and switches among the operation modes by being activated corresponding times.

10. The protective casing of claim 7, wherein the switch is a circuit controlled by the electronic device for switching among the operation modes.

11. The protective casing of claim 1, further comprising a back cover detachably accommodated in the accommodating space and used to house the electronic device.

12. The protective casing of claim 11, wherein the back cover comprises an engaging structure extending from a periphery of the back cover, and the engaging structure is used to engage the electronic device.

13. The protective casing of claim 12, wherein the engaging structure is arc-shaped claws.

14. The protective casing of claim 11, wherein the back cover comprises a resilient arm extending from a periphery of the back cover and corresponding to a power button of the electronic device.

15. The protective casing of claim 14, wherein the second casing comprises a key structure corresponding to the resilient arm of the back cover.

16. The protective casing of claim 11, wherein at least one recess is formed on a periphery of the back cover and is corresponding to at least one connector and/or button disposed on a periphery of the electronic device.

17. The protective casing of claim 16, wherein the at least one recess comprises a first recess formed on one side of the back cover and corresponding to a button disposed on one side of the electronic device.

18. The protective casing of claim 17, wherein the at least one recess further comprises a second recess formed on another side of the back cover and opposite to the first recess.

19. The protective casing of claim 1, wherein the first casing comprises a partition member disposed therein, the accommodating space comprises a first accommodating space above the partition member, and a second accommodating space between the partition member and a bottom of the first casing.

20. The protective casing of claim 19, wherein the circuit board is disposed in the second accommodating space and the electronic device is accommodated in the first accommodating space.
